(19) United States
(12) Patent Application Publication
(10) Pub. No.: US 2012/0049367 A1
(43) Pub. Date: Mar. 1, 2012

(54) SEMICONDUCTOR DEVICE AND MANUFACTURING METHOD OF SEMICONDUCTOR DEVICE

(75) Inventors: Tatsuo MIGITA, Oita (JP); Hirokazu Ezawa, Tokyo (JP); Soichi Yamashita, Kanagawa (JP)

(73) Assignee: Kabushiki Kaisha Toshiba, Tokyo (JP)

(21) Appl. No.: 13/217,746

(22) Filed: Aug. 25, 2011

(30) Foreign Application Priority Data
Aug. 31, 2010 (JP) 2010-195092

(51) Int. Cl. H01L 23/488; H01L 21/28

(52) U.S. Cl. 257/738; 438/614; 257/E23.023; 257/E21.158

(57) ABSTRACT

According to the embodiment, a pad electrode, a protective film, an under barrier metal film, and an electrode wiring portion are provided. The pad electrode is formed on a semiconductor substrate. The protective film is formed on the semiconductor substrate so that a surface of the pad electrode is exposed. The under barrier metal film is formed on the pad electrode and the protective film. The electrode wiring portion is formed on the pad electrode via the under barrier metal film. Moreover, a surface reflectance of the under barrier metal film is 30% or more at a wavelength of 800 nm, and a diameter of the electrode wiring portion is 140 μm or less.

### CROSS-REFERENCE TO RELATED APPLICATIONS

This application is based upon and claims the benefit of priority from the prior Japanese Patent Application No. 2010-195092, filed on Aug. 31, 2010; the entire contents of which are incorporated herein by reference.

### FIELD

Embodiments described herein relate generally to a semiconductor device and a manufacturing method of a semiconductor device.

### BACKGROUND

In order to achieve high integration and high performance of semiconductor devices, improvement of an operation speed of devices and increase in capacity of memories are required. For some devices, a chip is developed, in which a logic circuit and a large-capacity DRAM are packaged by Chip-On-Chip (CoC) connection instead of an eDRAM in one chip.

For example, when connecting a logic circuit and a large-capacity DRAM by the CoC connection, in order to achieve a broadband transfer speed, it is required to form a number of bumps in a specific area in a chip. For forming a number of bumps, a bump pitch and a bump diameter are required to be formed as small as possible.

Moreover, when forming a redistribution trace, a bump, or the like on a semiconductor substrate, a pattern opening is formed in a photosensitive material in some cases by a photolithography process. In this case, the photosensitive state of a photosensitive material sometimes changes due to diffuse reflection of light or the like depending on the surface state of a base, so that an opening shape is distorted or an opening diameter varies in some cases.

When the opening shape is distorted or the opening diameter varies, the height of bumps formed in the openings varies, which becomes a factor of decreasing reliability in the CoC connection, so that it is required to appropriately manage the surface state of a base of a photosensitive material.

### BRIEF DESCRIPTION OF THE DRAWINGS

FIG. 1A to FIG. 1C are cross-sectional views illustrating a manufacturing method of a semiconductor device according to a present embodiment;

FIG. 2A to FIG. 2C are cross-sectional views illustrating the manufacturing method of the semiconductor device according to the present embodiment;

FIG. 3A to FIG. 3C are cross-sectional views illustrating the manufacturing method of the semiconductor device according to the present embodiment;

FIG. 4A to FIG. 4C are cross-sectional views illustrating the manufacturing method of the semiconductor device according to the present embodiment;

FIG. 5 is a diagram illustrating a relationship between the reflectance of a Ti/Cu film and its surface state with respect to a wavelength of 800 nm; and

FIG. 6 is a cross-sectional view and a surface view illustrating a relationship between the reflectance of a base underlying a resist film and a resist opening diameter.

### DETAILED DESCRIPTION

In general, according to one embodiment, a pad electrode, a protective film, an under barrier metal film, and an electrode wiring portion are provided. The pad electrode is formed on a semiconductor substrate. The protective film is formed on the semiconductor substrate so that a surface of the pad electrode is exposed. The under barrier metal film is formed on the pad electrode and the protective film. The electrode wiring portion is formed on the pad electrode via the under barrier metal film. Moreover, a surface reflectance of the under barrier metal film is 30% or more at a wavelength of 800 nm, and a diameter of the electrode wiring portion is 140 μm or less.

A semiconductor device and a manufacturing method of a semiconductor device according to the embodiment will be explained below with reference to the drawings. The present invention is not limited to the embodiment.

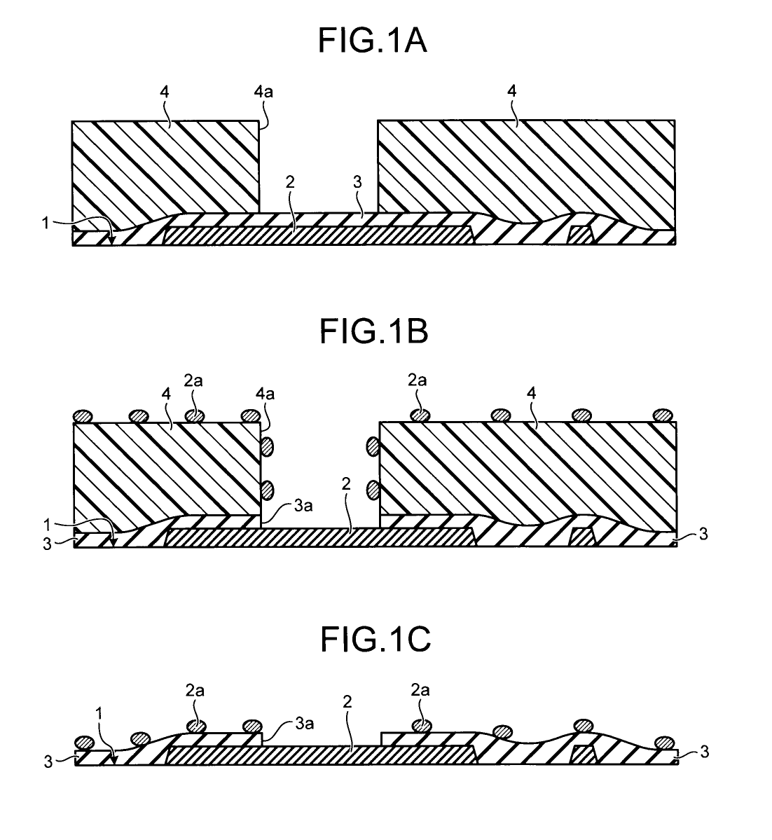

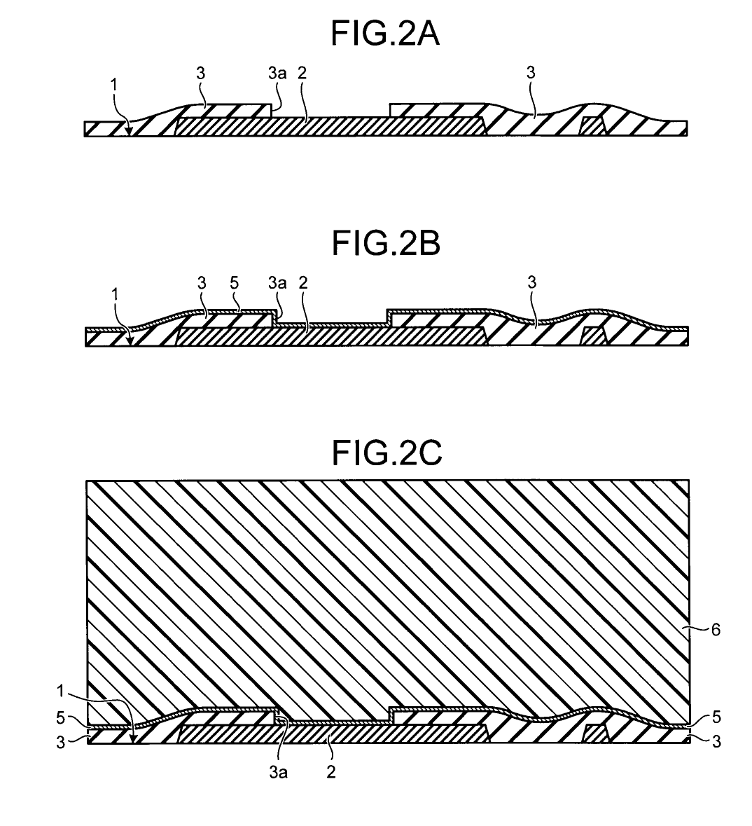

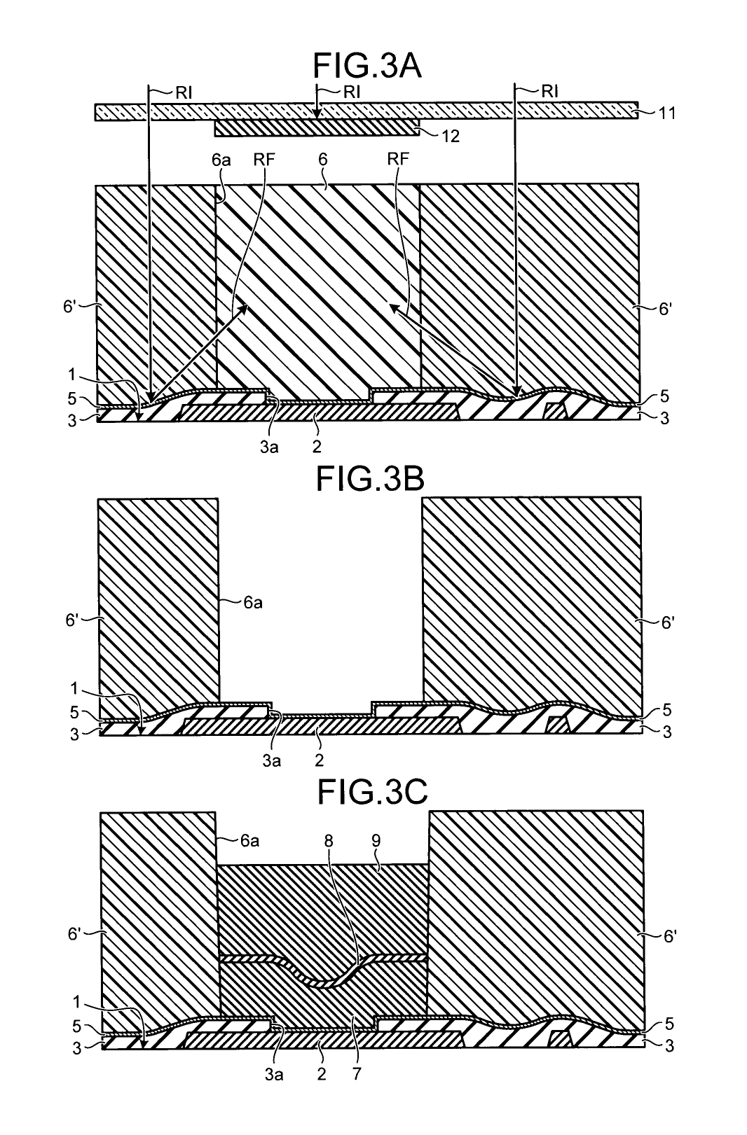

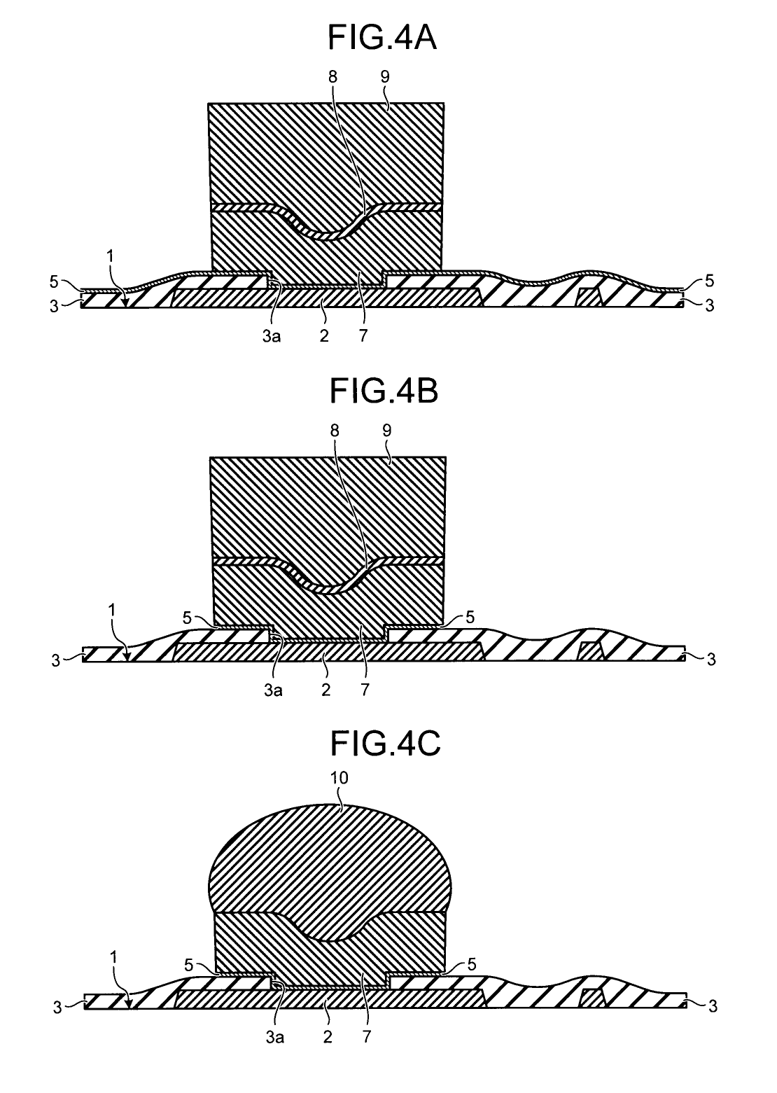

FIG. 1A to FIG. 1C, FIG. 2A to FIG. 2C, FIG. 3A to FIG. 3C, and FIG. 4A to FIG. 4C are cross-sectional views illustrating a manufacturing method of a semiconductor device according to the present embodiment.

In FIG. 1A, on a base material layer 1, a pad electrode 2 is formed and a protective film 3 is formed to cover the pad electrode 2. As the base material layer 1, for example, a semiconductor substrate on which an integrated circuit, such as a logic circuit or a DRAM, is formed can be used. Moreover, as the material of the pad electrode 2, for example, Al or Al-based metal can be used. Furthermore, as the material of the protective film 3, for example, an inorganic insulator, such as a silicon oxide film, a silicon oxynitride film, or a silicon nitride film, can be used.

Then, a resist pattern 4 having an opening 4a over the pad electrode 2 is formed on the protective film 3 by using the photolithography technology.

Next, as shown in FIG. 1B, an opening 3a is formed in the protective film 3 by performing anisotropic etching such as RIE on the protective film 3 with the resist pattern 4 as a mask. When forming the opening 3a in the protective film 3, the surface of the pad electrode 2 is etched and etching residues 2a of the pad electrode 2 scatter, so that the etching residues 2a adhere to the surface of the resist pattern 4.

Next, as shown in FIG. 1C, the resist pattern 4 on the protective film 3 is removed by a method such as ashing. When the resist pattern 4 is removed, the etching residues 2a remain on the protective film 3 and the etching residues 2a adhere to the surface of the protective film 3.

Next, as shown in FIG. 2A, the surface of the protective film 3 is etched to lift off the etching residues 2a, thereby removing the etching residues 2a from the surface of the protective film 3. As an etching method of the surface of the protective film 3, for example, when the surface of the protective film 3 is formed of an oxide film or a nitride film, wet etching using dilute hydrofluoric acid as chemicals can be used.

Next, as shown in FIG. 2B, an under barrier metal film 5 is formed on the pad electrode 2 and the protective film 3 by using a method such as sputtering, plating, CVD, ALD, or vapor deposition. As the under barrier metal film 5, for example, a stacked structure of Ti and Cu stacked thereon can be used. It is applicable to use a material such as TiN, TiW, W, Ta, Cr, or Co instead of Ti. Moreover, it is applicable to use a material such as Al, Pd, Au, or Ag instead of Cu.

The under barrier metal film 5 is formed on the protective film 3 after removing the etching residues 2a on the surface of the protective film 3, so that the surface roughness of the under barrier metal film 5 can be reduced compared with the case where the etching residues 2a on the surface of the protective film 3 are not removed, enabling to increase the surface reflectance of the under barrier metal film 5.

Next, as shown in FIG. 2C, a resist film 6 is formed on the under barrier metal film 5 by using a method such as spin coating. As the material of the resist film 6, negative photosensitive resist can be used.

Next, as shown in FIG. 3A, a latent image 6′ arranged around an opening 6a in FIG. 3B is formed in the resist film 6 by performing exposure on the resist film 6 with a reticle 11 on which a light shielding film 12 is formed as a mask.

When the material of the resist film 6 is negative photosensitive resist, exposure light RI is shielded at the opening 6a and the exposure light RI enters the resist film 6 around the opening 6a. Then, when the exposure light RI is transmitted through the resist film 6 and reaches the surface of the under barrier metal film 5, the exposure light RI diffusely reflects depending on the surface roughness of the under barrier metal film 5 and diffuse reflection light RF enters a portion of the resist film 6 to be removed as the opening 6a.

Next, as shown in FIG. 3B, the opening 6a arranged over the pad electrode 2 is formed in the resist film 6 by performing development on the resist film 6. When the opening diameter of the opening 6a is 140 μm or less, the surface reflectance of the base underlying the resist film 6 is preferably 80% or more at a wavelength of 800 nm.

Moreover, when the opening diameter of the opening 6a is 40 μm or less, the surface reflectance of the base underlying the resist film 6 is preferably 90% or more at a wavelength of 800 nm. Furthermore, when the opening diameter of the opening 6a is 20 μm or less, the surface reflectance of the base underlying the resist film 6 is preferably 98% or more at a wavelength of 800 nm.

In the process in FIG. 3A, when the diffuse reflection light RF enters the portion of the resist film 6 to be removed as the opening 6a, the latent image 6′ is formed also in the portion, so that the diameter of the opening 6a becomes small, which results in causing variation in the diameter of the opening 6a.

At this time, the surface reflectance of the base underlying the resist film 6 can be increased by removing the etching residues 2a on the surface of the protective film 3 before forming the under barrier metal film 5 on the protective film 3. Therefore, it is possible to reduce that the exposure light RI transmitted through the resist film 6 is diffusely reflected from the base underlying the resist film 6, so that entry of the diffuse reflection light RF into the portion of the resist film 6 to be removed as the opening 6a can be reduced. Consequently, the diameter of the opening 6a can be suppressed from becoming small, enabling to reduce variation in the diameter of the opening 6a.

The surface reflectance of the base underlying the resist film 6 is set to 80% or more at a wavelength of 800 nm when the opening diameter of the opening 6a is 140 μm or less. This is because, if the surface reflectance becomes smaller than 80%, the amount of the etching residues 2a remaining on the surface of the protective film 3 becomes large and therefore the effect of the variation in the diameter of the opening 6a increases.

Moreover, the surface reflectance is set to be larger as the opening diameter of the opening 6a becomes smaller. This is because the effect of the variation in the diameter of the opening 6a on the variation in the height of a bump electrode embedded in the opening 6a increases.

Next, as shown in FIG. 3C, a bump electrode is formed on the pad electrode 2 via the under barrier metal film 5 by sequentially embedding a barrier layer 7 and solder layers 8 and 9 in the opening 6a by electroplating. For example, Ni can be used for the material of the barrier layer 7, Cu can be used for the material of the solder layer 8, and Sn can be used for the material of the solder layer 9.

Next, as shown in FIG. 4A, the resist film 6 on the under barrier metal film 5 is removed by a method such as asking.

Next, as shown in FIG. 4B, the under barrier metal film 5 is etched with the bump electrode formed of the barrier layer 7 and the solder layers 8 and 9 as a mask, thereby removing the under barrier metal film 5 around the bump electrode formed of the barrier layer 7 and the solder layers 8 and 9.

Next, as shown in FIG. 4C, the solder layers 8 and 9 are reflowed, so that the solder layers 8 and 9 are alloyed to form an alloy solder layer 10 on the barrier layer 7.

The above processes can be performed in a state where the base material layer 1 is a wafer. Then, after the above processes, semiconductor chips can be cut out by singulating this wafer.

Variation in the diameter of the opening 6a is reduced, so that even when the amount of the barrier layer 7 and the solder layers 8 and 9 sequentially embedded in the opening 6a is kept constant regardless of the diameter of the opening 6a, variation in the height of the bump electrode formed of the barrier layer 7 and the solder layers 8 and 9 can be reduced, enabling to improve reliability in the CoC connection.

At this time, when the diameter of the bump electrode formed of the barrier layer 7 and the solder layers 8 and 9 is 140 μm or less, the surface reflectance of the under barrier metal film 5 is preferably 80% or more at a wavelength of 800 nm. Moreover, when the diameter of the bump electrode formed of the barrier layer 7 and the solder layers 8 and 9 is 40 μm or less, the surface reflectance of the under barrier metal film 5 is preferably 90% or more at a wavelength of 800 nm. Furthermore, when the diameter of the bump electrode formed of the barrier layer 7 and the solder layers 8 and 9 is 20 μm or less, the surface reflectance of the under barrier metal film 5 is preferably 98% or more at a wavelength of 800 nm.

In the above embodiment, the method of using a solder ball as the bump electrode is explained, however, a nickel bump, a gold bump, a copper bump, or the like can be used instead. Moreover, in the above embodiment, explanation is given for the method of using a stacked structure of Ti and Cu as the under barrier metal film 5, however, Ti or Cu can be used alone, Cr, Pt, W, or the like can be used alone, or a stacked structure of these metals can be used. Moreover, it is applicable to use a material such as TiN, TiW, W, Ta, Cr, or Co, or a stacked structure thereof instead of Ti.

Furthermore, as a joining method of the bump electrode in the CoC connection, metal joint, such as solder joint and alloy joint, can be used, or ACF (Anisotropic Conductive Film) bonding, NCF (Nonconductive Film) bonding, ACP (Anisotropic Conductive Paste) bonding, NCP (Nonconductive Paste) bonding, or the like can be used.

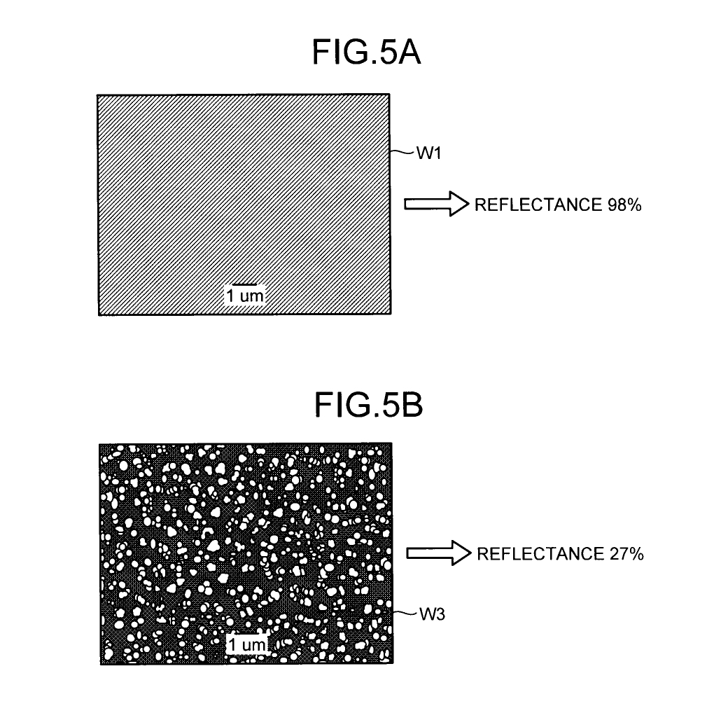

FIG. 5 is a diagram illustrating a relationship between the reflectance of a Ti/Cu film and its surface state with respect to a wavelength of 800 nm.

In FIG. 5, as a sample W1 of the base of the resist film 6 in the case where there is no etching residue 2a, one obtained by forming a Ti/Cu film (film thickness 200/300 μm) on a bare Si substrate by sputtering is used. The surface reflectance of this sample W1 is 98.3% at a wavelength of 800 nm.

Next, as a sample W3 of the base of the resist film 6 in the case where there are the etching residues 2a, one obtained by forming a Ti/Cu film (film thickness 200/300 μm) on the sample, which is obtained in the processes in FIG. 1B and FIG. 1C, by sputtering is used. In this sample W3, a silicon nitride film is used as the protective film 3. Moreover, it is confirmed that, in this sample W3, the etching residues 2a adhere to the protective film 3 and the surface of the Ti/Cu film is rough. The surface reflectance of this sample W3 is 30.9% at a wavelength of 800 nm.

The reflective film thickness monitor FE-3000 (manufactured by Otsuka Electronics Co., Ltd.) is used for measurement of the surface reflectance of the samples W1 and W3.

In this manner, there is a correlation between the presence or absence of the etching residue 2a under the Ti/Cu film and the surface reflectance of the Ti/Cu film, so that the surface reflectance of the Ti/Cu film decreases as the etching residue 2a under the Ti/Cu film increases. Therefore, the amount of the etching residues 2a under the Ti/Cu film can be evaluated by measuring the surface reflectance of the Ti/Cu film, so that variation in the diameter of the resist opening formed in the Ti/Cu film can be estimated.

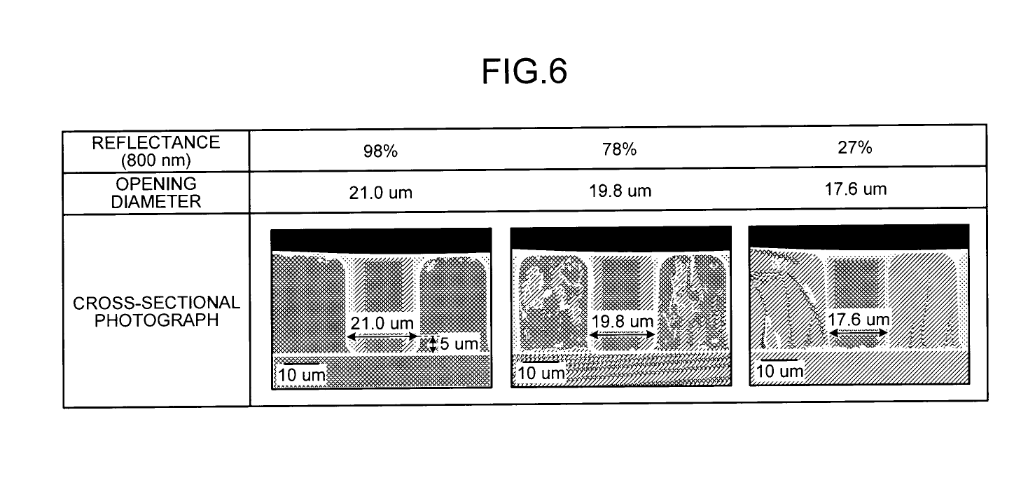

FIG. 6 is a cross-sectional view and a surface view illustrating a relationship between the reflectance of the base underlying the resist film and the resist opening diameter.

In FIG. 6, samples, whose surface reflectance at a wavelength of 800 nm is 98%, 78%, and 27%, are prepared as the base of the resist film. The surface roughness of the base of the resist film is varied for varying the surface reflectance of the base of the resist.

Then, the resist film is applied to these bases by spin coating and an opening is formed in these resist films under the same exposure condition and the same development condition. Then, the upper surface shape and the cross-sectional shape of the openings formed in these resist films are observed by a scanning electron microscope.

Consequently, the opening diameter becomes 21.0 μm in the sample whose surface reflectance is 98%, the opening diameter becomes 19.8 μm in the sample whose surface reflectance is 78%, and the opening diameter becomes 17.6 μm in the sample whose surface reflectance is 27%, so that it is confirmed that the opening diameter becomes smaller as the surface reflectance decreases.

In the above embodiment, explanation is given for the method of defining the surface state of the base underlying the resist film 6 for reducing variation in the diameter of the opening 6a by the surface reflectance of the base underlying the resist film 6, however, it is applicable to use a value obtained by converting the surface reflectance of the base underlying the resist film 6 into the surface roughness.

Moreover, in the above embodiment, explanation is given for the case of using a bump electrode as an electrode wiring portion as an example, however, it is applicable to use a pillar, a redistribution trace, a pad, or the like as the electrode wiring portion.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a pad electrode formed on a semiconductor substrate;
a protective film formed on the semiconductor substrate so that a surface of the pad electrode is exposed;
an under barrier metal film formed on the pad electrode and the protective film; and
an electrode wiring portion formed on the pad electrode via the under barrier metal film, wherein
a surface reflectance of the under barrier metal film is 30% or more at a wavelength of 800 nm, and
a diameter of the electrode wiring portion is 140 μm or less.

2. The semiconductor device according to claim 1, wherein
a surface reflectance of the under barrier metal film is 80% or more at a wavelength of 800 nm, and
a diameter of the electrode wiring portion is 40 μm or less.

3. The semiconductor device according to claim 1, wherein
a surface reflectance of the under barrier metal film is 98% or more at a wavelength of 800 nm, and
a diameter of the electrode wiring portion is 20 μm or less.

4. The semiconductor device according to claim 1, wherein the electrode wiring portion is a bump electrode.

5. The semiconductor device according to claim 4, wherein the bump electrode is a solder ball.

6. The semiconductor device according to claim 1, wherein the electrode wiring portion is a pillar, a redistribution trace, or a pad.

7. The semiconductor device according to claim 1, wherein the under barrier metal film has a stacked structure in which a lower layer is selected from any of Ti, TiN, TiW, W, Ta, Cr, and Co and an upper layer is a selected from any of Cu, Al, Pd, Au, and Ag.

8. The semiconductor device according to claim 1, wherein an integrated circuit is formed on the semiconductor substrate.

9. The semiconductor device according to claim 1, wherein the protective film is an inorganic insulator.

10. The semiconductor device according to claim 1, wherein an etching residue on the protective film is removed from a surface of the protective film.

11. A method of manufacturing a semiconductor device comprising:
forming a pad electrode on a semiconductor substrate;
forming a protective film on the semiconductor substrate to cover the pad electrode;
forming a first resist pattern having a first opening over the pad electrode on the protective film;
forming a second opening that exposes the pad electrode in the protective film by etching the protective film with the first resist pattern as a mask;
removing the first resist pattern on the protective film in which the second opening is formed;
removing an etching residue of the pad electrode from a surface of the protective film by etching the surface of the protective film;
forming an under barrier metal film on the pad electrode and the protective film in which the etching residue of the pad electrode is removed from the surface;
forming a second resist pattern having a third opening over the pad electrode on the under barrier metal film;
forming an electrode wiring portion embedded in the third opening on the under barrier metal film;
removing the second resist pattern on the under barrier metal film on which the electrode wiring portion is formed; and
removing the under barrier metal film around the electrode wiring portion by etching the under barrier metal film with the electrode wiring portion as a mask.

12. The method according to claim 11, wherein
a surface reflectance of a base underlying the second resist pattern is 30% or more at a wavelength of 800 nm, and
an opening diameter of the third opening is 140 μm or less.

13. The method according to claim 11, wherein
a surface reflectance of a base underlying the second resist pattern is 80% or more at a wavelength of 800 nm, and
an opening diameter of the third opening is 40 μm or less.

14. The method according to claim 11, wherein
a surface reflectance of a base underlying the second resist pattern is 98% or more at a wavelength of 800 nm, and
an opening diameter of the third opening is 20 μm or less.

15. The method according to claim 11, wherein the electrode wiring portion is a bump electrode.

16. The method according to claim 15, wherein the bump electrode is a solder ball.

17. The method according to claim 11, wherein the electrode wiring portion is a pillar, a redistribution trace, or a pad.

18. The method according to claim 11, wherein the under barrier metal film has a stacked structure in which a lower layer is selected from any of Ti, TiN, TiW, W, Ta, Cr, and Co and an upper layer is a selected from any of Cu, Al, Pd, Au, and Ag.

19. The method according to claim 11, wherein an integrated circuit is formed on the semiconductor substrate.

20. The method according to claim 11, wherein
the protective film is an inorganic insulator, and
the etching residue of the pad electrode is removed from the surface of the protective film by wet etching using dilute hydrofluoric acid as a chemical.
